(19) United States
(12) Patent Application Publication
(10) Pub. No.: US 2024/0012973 A1
(43) Pub. Date: Jan. 11, 2024

(54) WAVEFORM STIMULUS GENERATION

(71) Applicant: Xilinx, Inc., San Jose, CA (US)

(72) Inventors: Sandeep S. Deshpande, Longmont, CO (US); Saikat Bandyopadhyay, San Jose, CA (US)

(73) Assignee: Xilinx, Inc., San Jose, CA (US)

(21) Appl. No.: 17/862,061

(22) Filed: Jul. 11, 2022

(51) Int. Cl. G06F 30/367

(52) U.S. Cl. CPC G06F 30/367

(57) ABSTRACT

Simulation of a waveform in a circuit simulation includes preparing, in response to a programming interface call by a testbench, a schedule of states of a signal at two or more intervals in the simulation by a simulator. The programming interface call specifies a sequence of the states and indicates durations of the states during the simulation. The signal is set to a first state of the sequence by the simulator during the simulation and then to a second state of the sequence according to the schedule.

### TECHNICAL FIELD

The disclosure generally relates to simulating waveform stimuli in a circuit simulation.

### BACKGROUND

The Vivado simulator (“XSIM”) from Xilinx, Inc., provides C-based interface functions that enable users to create testbenches for circuit simulation. Simulating waveform stimuli of signals to a circuit entails driving values on ports of the circuit.

Current mechanisms for driving the signal values of a waveform involve invoking an application programming interface (“API”) for each change in signal state. For example, an API call is made to specify the signal state, and the simulation is run to advance the simulation for a selected number of clock cycles. After advancing the simulation, another API call can be made to change the signal state.

### SUMMARY

A disclosed method of simulating an input waveform to a circuit simulation includes preparing, in response to a programming interface call by a testbench, a schedule of states of a signal at two or more intervals in a circuit simulation by a simulator, respectively. The programming interface call specifies a sequence of the states and indicates durations of the states during the simulation. The method includes setting the signal to a first state of the sequence by the simulator during the simulation according to the schedule, and setting the signal to a second state of the sequence by the simulator during the simulation according to the schedule.

Another disclosed method includes preparing, in response to a programming interface call by a testbench, a schedule of states of a set of signals at two or more intervals in a circuit simulation by a simulator, respectively. The programming interface call specifies a sequence of values and indicates durations of the values during the simulation, and each value specifies respective states of the signals of the set of signals. The method includes setting the signals of the set of signals to respective first states indicated by a first value of the sequence by the simulator during the simulation according to the schedule, and setting signals of the set of signals to respective second states indicated by a second value of the sequence by the simulator during the simulation according to the schedule.

A disclosed system includes one or more computer processors configured to execute program code and a memory arrangement coupled to the one or more computer processors. The memory arrangement is configured with instructions that when executed by the one or more computer processors cause the one or more computer processors to perform operations including preparing, in response to a programming interface call by a testbench, a schedule of states of a signal at two or more intervals in a circuit simulation by a simulator, respectively. The programming interface call specifies a sequence of the states and indicates durations of the states during the simulation. The operations include setting the signal to a first state of the sequence by the simulator during the simulation according to the schedule, and setting the signal to a second state of the sequence by the simulator during the simulation according to the schedule.

Other features will be recognized from consideration of the Detailed Description and Claims, which follow.

### BRIEF DESCRIPTION OF THE DRAWINGS

Various aspects and features of the methods and systems will become apparent upon review of the following detailed description and upon reference to the drawings in which:

FIG. 1 shows a system for simulating the behavior of a circuit based on a circuit design;

FIG. 2 shows a flowchart of operations of an exemplary testbench and simulator and use of the disclosed waveform API in simulating the behavior of a circuit based on a circuit design; and

FIG. 3 is a block diagram illustrating an exemplary data processing system.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

Current approaches for simulating waveform stimuli are simple and intuitive. An API call can be made to set the signal state on a port for desired time interval, and another API call can be made to change the state on the port after expiration of the time interval. Though the current approach is straightforward, excessive demands and inefficient use of computing resources can result from scenarios in which the signal state needs to be toggled repeatedly in a predictable pattern. Not only can numerous API calls create computational inefficiencies, but simulating complex waveforms can make the testbench program code verbose and complicated.

The disclosed approaches reduce demands for computing resources in simulating the input of waveform stimuli in a circuit simulation. According to the disclosed approaches, the properties of a waveform can be specified through a single API call, and the simulator can apply the different states of the signal during simulation without further API calls. The disclosed approaches significantly reduce demand for computing resources in simulating periodic signals.

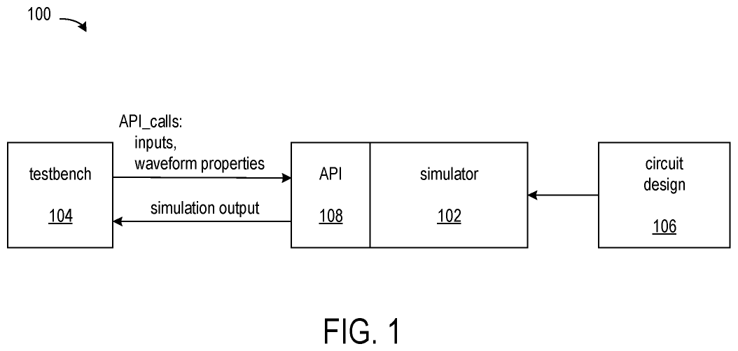

FIG. 1 shows a system for simulating the behavior of a circuit based on a circuit design. The system 100 includes a simulator 102 and a testbench that simulate behavior of a circuit specified by the circuit design 106. The simulator 102 can be an event-driven simulator, such as the Vivado simulator, from Xilinx, Inc. The Vivado simulator supports functional and timing simulations for VHDL, Verilog, SystemVerilog (SV), and mixed VHDL/Verilog or VHDL/SV designs. The simulator can compile the components of the design 106 into a simulation model (not shown).

The testbench 104 can be a high-level language-based (HLL-based) program, such as C or C++, that interacts with the simulator 102 through function calls to the API 108 of the simulator. Generally, the testbench instantiates and initializes the design and generates and applies stimuli during simulation. The testbench can also monitor the simulation output to check for functional correctness, display simulation output, and/or write the simulation output to a file.

According to the disclosed methods and systems, through a single function call (“waveform API call”) to the API 108, the testbench can direct the simulator to change the state of a signal multiple times and repeat a desired periodic waveform pattern during the simulation. The methods and systems avoid verbose and complicated program code sequences in the testbench and improve simulation performance computer efficiency by eliminating multiple API function calls to change the state of a simulated signal.

The waveform API call specifies a sequence of two or more value-time pairs for a particular port of the design. The value specifies the state of the signal, and the time generally specifies the duration of the signal state during simulation. For example, the API call can specify the following parameters: port identifier, value1-time1, value2-time2, . . .

According to an exemplary approach, the time element of the value-time pairs can be specified as an offset in simulation time units (e.g., nanoseconds). The offset of the first value-time pair of the sequence can be relative to the simulation time at which the API call is made to the simulator. The offsets in the value-time pairs that follow the first pair are based relative to the simulation time at which the value of the previous pair in the sequence was applied.

For example, the testbench can call the waveform API at simulation time 500 for a particular port and specify value1=1, time1=50; value2=0, time2=100; value3=1, time3=50; and value4=0, time4=25. The simulator applies: value1=1 at simulation time 550 (current simulation time 500+offset 50); applies value2=0 at simulation time 650; applies value3=1 at simulation time 700; and applies value4=0, at simulation time 725.

The single waveform API call can also specify that the waveform pattern be repeated. The waveform API call can specify a “repeat-cycle” time that indicates a duration between consecutive cycles of the waveform pattern. According to an exemplary approach, the repeat-cycle time can be specified as a simulation time offset. Continuing the previous example, the waveform API call can specify a repeat-cycle time of 100. Based on the specified repeat-cycle time in the API call, the simulator will repeat the waveform cycle at simulation time 825, which is 100 simulation time units after application of the last signal value in the sequence.

The single waveform API call can also specify a simulation time at which application of the waveform is to be cancelled. The “cancel-time” can be specified as a simulation time offset from the simulation start time of the waveform. Continuing with the previous example with a repeat-cycle=100, if the cancel-time=1100, the simulator will cease repeating the waveform at simulation time 1650 (550+1100, which is 4 cycles of the waveform).

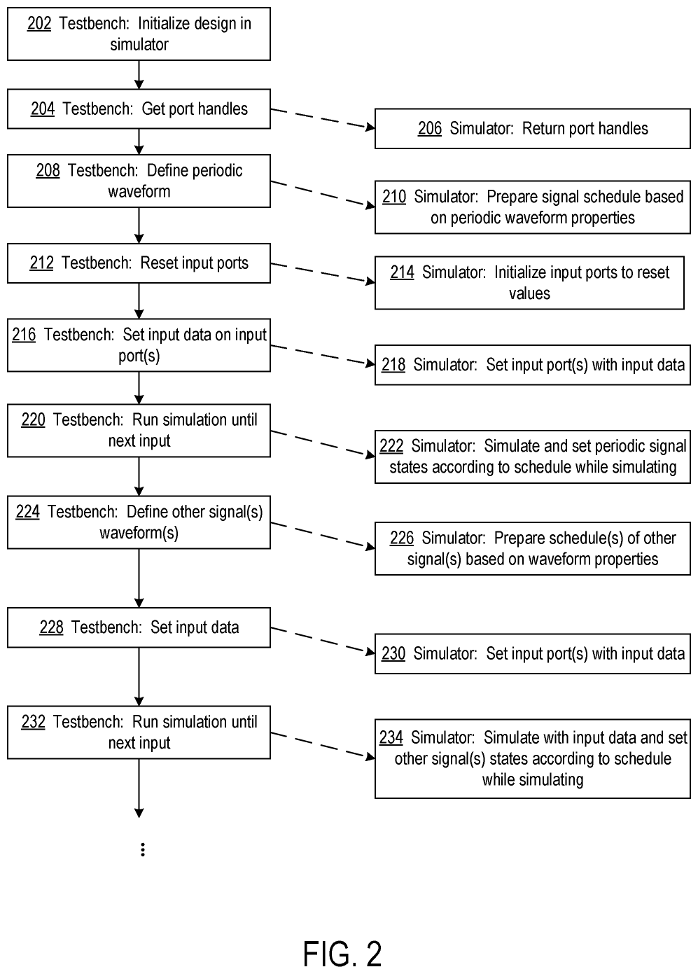

FIG. 2 shows a flowchart of operations of an exemplary testbench and simulator and use of the disclosed waveform API in simulating the behavior of a circuit based on a circuit design. At block 202 the testbench initializes the design with the simulator, and at block 204 the testbench gets one or more port handles of the circuit design from the simulator. A port handle is an identifier of an input port or an output port of the design established by the simulator and enables the testbench to indicate to the API ports for providing input data or receiving output data. At block 206, the simulator returns the requested port handle(s) to the testbench. The dashed line from block 202 to block 204 signifies an API call by the testbench to the simulator to obtain the port handle(s), and the other dashed lines in FIG. 2 signify other API calls by the testbench to the simulator.

At block 208, the testbench defines a waveform in a waveform API call to the simulator. The API call can define the waveform as a sequence of states of a signal over two or more timing intervals of the simulation, and the waveform pattern can be repeated. For example, the waveform can be periodic, such as that of a clock signal. The waveform API call can specify timing of the sequence of states of the signal with respective offset values associated with the signal states in the sequence. Each offset value can be a simulation interval expressed in a unit of time (e.g., nanoseconds).

The waveform API call can instruct the simulator to repeat the waveform pattern by specifying a repeat-cycle time in the call. The repeat-cycle time specifies the simulation timing interval/duration between successive cycles of the sequence of signal states. A cancel time can be specified in the waveform API call to instruct the simulator when to stop repeating the sequence of states of the waveform pattern.

In response to the waveform API call, at block 210, the simulator prepares a schedule of states of the signal according to the properties of the waveform specified in the API call. The schedule of states can be events scheduled to occur at simulation times derived from the value-time pairs of the API call, with each event applying the specified signal state during the simulation. The events scheduled by the simulator include a first waveform event that is to occur at a simulation time that is offset by the time element of the first value-time pair, from the simulation time at which the waveform API call is made (current time+offset). The first waveform event applies the value element of the value-time pair to the port specified in the API call. For each value-time pair in the sequence other than the first value-time pair, the event generated by the simulator is scheduled to occur at a simulation time that is offset from the simulation time at which the preceding state in the sequence was applied, by the time element of that value-time pair.

According to the exemplary approach, the waveform API call can specify the repeat-cycle time as an offset that indicates a duration between repetitions of the sequence. In response to the repeat-cycle time, the simulator determines the timing between setting the signal to a last state in the sequence and setting the signal to the first state in the sequence for the next cycle of the waveform pattern. The simulator prepares a schedule of events in which the sequence is repeated, with the first event of each repetition scheduled to occur the number of units of simulation time indicated by the offset after the last event of the previous repetition.

According to the exemplary approaches, the cancel time can be specified in the waveform API call as a simulation time offset. In response to the cancel time in the API call, the simulator determines the simulation time to stop repeating the waveform pattern based on the simulation time at which the waveform is to be started and the cancel time offset. ((simulation time of waveform API call)+(time element. of first value-time pair in the sequence)+(cancel time)).

At block 212, the testbench calls on the simulator to reset the input ports of the design, and in response, at block 214, the simulator initializes the input ports to the “reset values,” which are initial values expected as input by the design at startup.

At block 216 the testbench sets input data on one or more input ports of the design by making one or more API calls to the simulator. The API calls specify the port handles and input data to be applied on those ports. The input data is data prepared for testing the circuit design in the simulation. At block 218, the simulator sets values on the inputs ports according to the input data specified in the API call.

At block 220, the testbench instructs the simulator to run the simulation, and at block 222, the simulator simulates behavior of the circuit based on the specified input data and the scheduled waveform events from block 210. In processing waveform events during the simulation, such as the waveform events for a port scheduled at block 210, the simulator applies the values to the port at the scheduled simulation times. Upon completion of a sequence of waveform events and in response to the specification of a repeat-cycle time specified in the waveform API call (e.g., at block 208), the simulator can schedule another sequence of waveform events to repeat the waveform and continue the simulation. The simulator continues the simulation as instructed by the testbench (block 220). For example, the simulation can continue by running freely for a specific number of clock cycles, continue by stepping the clock based on interactive user input, or continue until a specified logic state is reached.

At block 224, the testbench can, for example, call the waveform API to define another signal waveform after the simulation has run for some time. The testbench can make multiple waveform API calls for the simulation to schedule waveform events for multiple ports if desired for testing. In response to the waveform API call, the simulator at block 226 prepares a schedule of waveform events. The simulation time at which the waveform API call is made and the time elements of the value-time pairs are used by the simulator to determine the event schedule.

According to the disclosed approaches, each value element of the value-time pairs in a waveform API call can specify multiple signal values for a set of signals, such as a multi-signal bus port. Each value can be a multi-bit value in which the bits specify respective states of the signals of the set of signals. The time elements of the value-time pairs can be as described above. The simulator, in response to the waveform API call, prepares a schedule of waveform events for the multi-signal port. The simulator schedules the timing of the events as described above.

Each event generated by the simulator sets the signals of the port to respective states indicated by bits of the value of a value-time pair in the sequence specified by the waveform API call. As with repeat-cycle times described above for single signal ports, the waveform API call for a multi-signal port a can specify a repeat-cycle time, and the simulator schedules additional cycles of the sequence accordingly. Also, the waveform API call can specify a cancel-time for the waveform on a multi-signal port.

The operations of blocks 228, 230, 232, and 234 by the testbench and simulator are as described above for blocks 216, 218, 220, and 222, and the testbench can continue with additional input data and/or signal waveforms according to testing requirements.

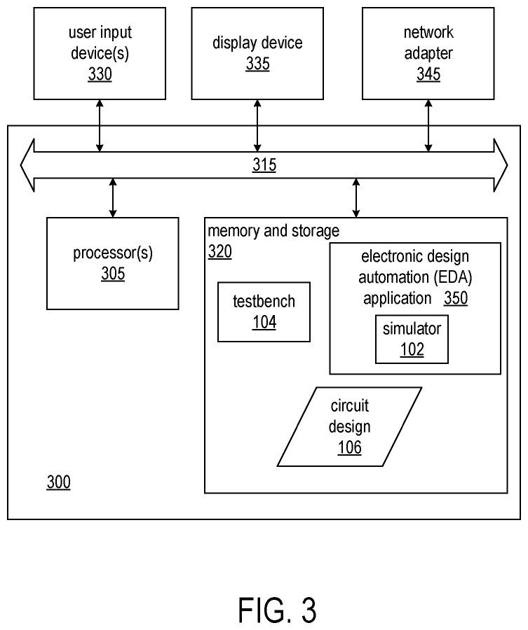

FIG. 3 is a block diagram illustrating an exemplary data processing system (system) 300. System 300 is an example of an EDA system. As pictured, system 300 includes at least one processor circuit (or “processor”), e.g., a central processing unit (CPU) 305 coupled to memory and storage arrangement 320 through a system bus 315 or other suitable circuitry. System 300 stores program code and circuit design 106 within memory and storage arrangement 320. Processor 305 executes the program code accessed from the memory and storage arrangement 320 via system bus 315. In one aspect, system 300 is implemented as a computer or other data processing system that is suitable for storing and/or executing program code. It should be appreciated, however, that system 300 can be implemented in the form of any system including a processor and memory that is capable of performing the functions described within this disclosure.

Memory and storage arrangement 320 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 300 may also include one or more cache memories (not shown) that provide temporary storage of at least some program code and data in order to reduce the number of times program code and data must be retrieved from local memory and persistent storage during execution.

Input/output (I/O) devices such as user input device(s) 330 and a display device 335 may be optionally coupled to system 300. The I/O devices may be coupled to system 300 either directly or through intervening I/O controllers. A network adapter 345 also can be coupled to system 300 in order to couple system 300 to other systems, computer systems, remote printers, and/or remote storage devices through intervening private or public networks. Modems, cable modems, Ethernet cards, and wireless transceivers are examples of different types of network adapter 345 that can be used with system 300.

Memory and storage arrangement 320 may store an EDA application 350. EDA application 350, being implemented in the form of executable program code, is executed by processor(s) 305. As such, EDA application 350 is considered part of system 300. System 300, while executing EDA application 350, receives and operates on circuit design 106. In one aspect the EDA application can include simulator 102, and the system 300 can execute testbench 104, which can also be considered part of the system 300. The EDA application 350 can also perform a design flow on circuit design 106, and the design flow may include synthesis, mapping, placement, routing. The system 300 can also generate implementation data for making an integrated circuit, such as a programmed FPGA of a fabricated application-specific (ASIC).

EDA application 350, circuit design 106, circuit design 360, and any data items used, generated, and/or operated upon by EDA application 350 are functional data structures that impart functionality when employed as part of system 300 or when such elements, including derivations and/or modifications thereof, are loaded into an IC such as a programmable IC causing implementation and/or configuration of a circuit design within the programmable IC.

Though aspects and features may in some cases be described in individual figures, it will be appreciated that features from one figure can be combined with features of another figure even though the combination is not explicitly shown or explicitly described as a combination.

The methods and system are thought to be applicable to a variety of systems for simulating waveform stimuli in a circuit simulation. Other aspects and features will be apparent to those skilled in the art from consideration of the specification. It is intended that the specification and drawings be considered as examples only, with a true scope of the invention being indicated by the following claims.

What is claimed is:

1. A method comprising:
preparing, in response to a programming interface call by a testbench, a schedule of states of a signal at two or more intervals in a circuit simulation by a simulator, respectively, wherein the programming interface call specifies a sequence of the states and indicates durations of the states during the simulation;
setting the signal to a first state of the sequence by the simulator during the simulation according to the schedule; and
setting the signal to a second state of the sequence by the simulator during the simulation according to the schedule.

2. The method of claim 1, wherein the signal is a periodic signal and further comprising repeating the setting of the signal to the first state and setting of the signal to the second state.

3. The method of claim 2, wherein:
the programming interface call specifies a repeat-cycle time that indicates a duration between cycles of setting the signal to the first state and setting of the signal to the second state; and
preparing the schedule specifies the duration between the cycles of setting the signal to the second state in one cycle and setting the signal to the first state in a next cycle.

4. The method of claim 1, wherein:
the programming interface call specifies a cancel time that indicates a simulation time to stop the repeating of the setting of the signal to the first state and setting of the signal to the second state; and
preparing the schedule specifies the simulation time to stop the repeating of the setting of the signal to the first state and setting of the signal to the second state.

5. The method of claim 1, wherein:
the durations of the states of the signal are specified in the programming interface call by offsets associated with the states in the sequence, respectively; and
preparing the schedule determines timing of the first state of the signal based on a current simulation time and the associated offsets, wherein the current simulation time is a simulation time at which the programming interface call made.

6. The method of claim 5, further comprising:
performing the circuit simulation in response to initial input signals from the testbench; and
wherein preparing the schedule is in response to the programming interface call made after the simulation on the initial input signals, and the current simulation time is a simulation time at which the programming interface call made.

7. The method of claim 1, wherein preparing the schedule determines timing for setting the signal to each state other than the first state in the sequence, based on the associated offset and a simulation time at which the signal is to be set to a preceding state in the sequence.

8. The method of claim 7, wherein:
the programming interface call specifies a repeat-cycle time; and
preparing the schedule determines timing between setting the signal to a last state in the sequence and setting the signal to the first state in the sequence based on a simulation time of setting the signal to the last state in the sequence, offset by the repeat-cycle time.

9. A method comprising:
preparing, in response to a programming interface call by a testbench, a schedule of states of a set of signals at two or more intervals in a circuit simulation by a simulator, respectively, wherein the programming interface call specifies a sequence of values and indicates durations of the values during the simulation, and each value specifies respective states of the signals of the set of signals;
setting the signals of the set of signals to respective first states indicated by a first value of the sequence by the simulator during the simulation according to the schedule; and
setting signals of the set of signals to respective second states indicated by a second value of the sequence by the simulator during the simulation according to the schedule.

10. The method of claim 9, wherein the signals of the set of signals are periodic signals and further comprising repeating the setting of the signals of the set of signals to the respective first states and setting of the signals to the respective second states.

11. The method of claim 10, wherein:
the programming interface call specifies a repeat-cycle time that indicates a duration between cycles of setting the signals of the set of signals to the respective first states and setting of the signals of the set of signals to the respective second states; and
preparing the schedule specifies the duration between the cycles of setting the signals of the set of signals to the respective second states in one cycle and setting the signals of the set of signals to the respective first states in a next cycle.

12. The method of claim 9, further comprising:
wherein the programming interface call specifies a cancel time that indicates a simulation time to stop the repeating of the setting of the set of signals to the respective first states and setting of the set of signals to the respective second states; and
the preparing of the schedule specifies the simulation time to stop the repeating of the setting of the set of signals to the respective first states and setting of the set of signals to the respective second states.

13. The method of claim 9, wherein:
the durations of the respective first states and respective second states of the set of signals are specified in the programming interface call by offsets associated with the first value and the second value in the sequence, respectively; and
the preparing of the schedule determines timing of the respective first states and the respective second states of the set of signals based on a current simulation and the associated offsets, wherein the current simulation time is a simulation time at which the programming interface call made.

14. The method of claim 13, further comprising:
performing the circuit simulation in response to initial input signals from the testbench; and
wherein preparing the schedule is in response to the programming interface call made after the simulation on the initial input signals.

15. A system, comprising:
one or more computer processors configured to execute program code; and
a memory arrangement coupled to the one or more computer processors, wherein the memory arrangement is configured with instructions that when executed by the one or more computer processors cause the one or more computer processors to perform operations including:
preparing, in response to a programming interface call by a testbench, a schedule of states of a signal at two or more intervals in a circuit simulation by a a simulator, respectively, wherein the programming interface call specifies a sequence of the states and indicates durations of the states during the simulation;
setting the signal to a first state of the sequence by the simulator during the simulation according to the schedule; and
setting the signal to a second state of the sequence by the simulator during the simulation according to the schedule.

16. The system of claim 15, wherein the signal is a periodic signal and the memory arrangement is further configured with instructions that when executed by the one or more computer processors cause the one or more computer processors to repeat setting the signal to the first state and setting of the signal to the second state.

17. The system of claim 16, wherein:
the programming interface call specifies a repeat-cycle time that indicates a duration between cycles of setting the signal to the first state and setting of the signal to the second state; and
the instructions for preparing the schedule include instructions that specify the duration between the cycles of setting the signal to the second state in one cycle and setting the signal to the first state in a next cycle.

18. The system of claim 15, wherein:
the programming interface call specifies a cancel time that indicates a simulation time to stop the repeating of the setting of the signal to the first state and setting of the signal to the second state; and
the instructions for preparing the schedule includes instructions that specify the simulation time to stop the repeating of the setting of the signal to the first state and setting of the signal to the second state.

19. The system of claim 15, wherein:
the durations of the states of the signal are specified in the programming interface call by offsets associated with the states in the sequence, respectively; and
the instructions for preparing the schedule include instructions that determine timing of the first state of the signal based on a current simulation time and the associated offsets, wherein the current simulation time is a simulation time at which the programming interface call made.

20. The system of claim 19, the memory arrangement is further configured with instructions that when executed by the one or more computer processors cause the one or more computer processors to perform operations including:
performing the circuit simulation in response to initial input signals from the testbench; and
wherein the instructions for preparing the schedule are executed is in response to the programming interface call made after the simulation on the initial input signals, and the current simulation time is a simulation time at which the programming interface call made.
